(19) United States
(12) Patent Application Publication
(10) Pub. No.: US 2011/0284068 A1
(43) Pub. Date: Nov. 24, 2011

(54) PASSIVATION METHODS AND APPARATUS FOR ACHIEVING ULTRA-LOW SURFACE RECOMBINATION VELOCITIES FOR HIGH-EFFICIENCY SOLAR CELLS

(75) Inventors: Mehrdad M. Moslehi, Los Altos, CA (US); Karl-Josef Kramer, San Jose, CA (US); Anand Deshpande, San Jose, CA (US); Rafael Ricolcol, Fremont, CA (US); Sean M. Seutter, San Jose, CA (US)

(73) Assignee: SOLEXEL, INC., Milpitas, CA (US)

(21) Appl. No.: 13/092,942

(22) Filed: Apr. 23, 2011

Related U.S. Application Data
(60) Provisional application No. 61/327,506, filed on Apr. 23, 2010.

(51) Int. Cl. H01L 31/0216; H01L 31/18; H01L 31/20; B82Y 99/00; B82Y 20/00

(52) U.S. Cl. 136/256; 438/69; 977/755; 257/E31.12; 977/948

(57) ABSTRACT

The disclosed subject matter provides a method and structure for obtaining ultra-low surface recombination velocities from highly efficient surface passivation in crystalline silicon substrate-based solar cells by utilizing a bi-layer passivation scheme which also works as an efficient ARC. The bi-layer passivation consists of a first thin layer of wet chemical oxide or a thin hydrogenated amorphous silicon layer. A second layer of amorphous hydrogenated silicon nitride film is deposited on top of the wet chemical oxide or amorphous silicon film. This deposition is then followed by annealing to further enhance the surface passivation.

This application claims the benefit of provisional patent application 61/327,506 filed on Apr. 23, 2010, which is hereby incorporated by reference.

### FIELD

This disclosure relates in general to the field of photovoltaics and solar cells, and more particularly to surface passivation of silicon solar cells.

### DESCRIPTION OF THE RELATED ART

The performance of semiconductor crystalline silicon based devices, such as solar cells, depends strongly on minority carrier recombination in the bulk as well as surface regions of the cell itself. Consequently, reducing the surface recombination is of the utmost importance for these devices. Surface recombination effects are becoming progressively more important as silicon semiconductor device dimensions, such as solar cell wafer thickness, are reduced. The surface passivation of silicon using amorphous films based on hydrogenated silicon compounds has been the subject of intense research in recent years, particularly for solar cell applications. Significant reductions in the effective surface recombination velocity (seff) at the silicon interface have been reported when passivated with amorphous silicon, amorphous silicon oxide, amorphous silicon nitride, and amorphous silicon carbide. Studied films include amorphous, hydrogenated silicon nitride (SixNy:Hz), hereafter referred to as SiNx films. These films are typically deposited by plasma-enhanced chemical vapor deposition (PECVD) at low temperature (400° C.) using silane gas and other reactant gases such as ammonia or nitrogen. Current methods have demonstrated that the surface passivation is maximized when silicon-rich SiNx films with refractive index greater than 2.3 were used, but such films also suffer from loss of light trapping efficiency by absorption in the passivation layer.

Historically, front (light receiving) side passivation is reported to be better utilizing thermal oxide which provides relatively low surface recombination velocities, and there have been extensive studies on the impact of silicon nitride deposition conditions and their impact on passivation. With the current efforts on increasing the solar cell efficiency for crystalline silicon based devices through cell structure development, reducing surface recombination velocity is critical. In conventional cell structures with front and back contact or all back contact structures, passivation reducing front surface recombination and good light trapping properties are key requirements for the front side light receiving surface. Often these two key requirements conflict due to the material properties of SiNx layers. Deposition parameters used for the passivation/ARC layer also pose restrictions on the device manufacturing due to requirements such as the use of low temperatures in subsequent processing steps and the restricted window of temperature with which passivation may be achieved.

As applied to thin film structures, low temperature deposition is critical because of the mechanically weak thin substrates. However, many current passivation methods, such as the use of thermal oxide and silicon nitride as passivation layers, require high temperature processes to be effective as both a passivation and light trapping layer.

### SUMMARY

Therefore a need has arisen for superior surface passivation methods which provide enhanced optical properties for crystalline silicon substrates and may be processed at low temperatures. In accordance with the disclosed subject matter, bi-layer passivation methods and structures are provided which substantially eliminate or reduces disadvantage and problems associated with previously developed passivation methods.

According to one aspect of the disclosed subject matter, a bi-layer passivation scheme for forming a chemical oxide thin film and depositing an amorphous silicon nitride thin film is provided. According to another aspect of the disclosed subject matter, a bi-layer passivation scheme for depositing an amorphous silicon thin film and depositing an amorphous silicon nitride thin film is provided.

Technical advantages of the disclosed subject matter include low processing temperatures, improved surface passivation, and increased optical properties for silicon substrates.

The disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGURES and detailed description. It is intended that all such additional systems, methods, features and advantages included within this description, be within the scope of the accompanying claims.

### BRIEF DESCRIPTIONS OF THE DRAWINGS

For a more complete understanding of the disclosed subject matter and advantages thereof, reference is now made to the following description taken in conjunction with the accompanying drawings in which like reference numbers indicate like features and wherein:

FIG. 1 is a graph comparing surface passivation quality (Seff) with PECVD SiNx film refractive index (RI) on a dual layer stack with wet chemical oxide showing tuning deposition parameters of SiN at 400° C.;

FIG. 2 is a graph showing a passivation quality comparison of 400° C. amorphous Si/SiN and chem-ox/400 C SiN dual layer stack with thermal (high-temp) oxide/SiN stack;

FIG. 3 is a graph showing optical parameters i.e. refractive index(n) and extinction coefficient (k) vs wavelength for dual layer stack vs Single layer SiN showing matched parameters with thin amorphous Si layer;

FIG. 4 is a graph showing passivation performance at 250° C. of dual layer stack (a-Si 10A and 30A/SiN and chem-ox/SiN);

FIG. 5 is a graph showing passivation (Seff) vs amorphous Si layer thickness in a-Si/SiN stack with varying processing temperatures; and

FIG. 6 is a graph showing passivation (Seff) vs temperature in a-Si/SiN stack with varying processing temperatures.

### DETAILED DESCRIPTION OF THE SPECIFIC EMBODIMENTS

The following description is not to be taken in a limiting sense, but is made for the purpose of describing the general principles of the present disclosure. The scope of the present disclosure should be determined with reference to the claims. Exemplary embodiments of the present disclosure are described and illustrated in the drawings, like numbers being used to refer to like and corresponding parts of the various drawings.

High-quality surface passivation is needed to obtain low surface recombination velocities and high effective minority carrier lifetimes on crystalline silicon substrates for various applications, including solar photovoltaic cells. Historically superior surface passivation techniques have included using a high temperature thermal oxidation process. However, these high temperature processes may be undesirable for the manufacture of thin film solar cells in part due to the mechanically weak nature of thin film silicon substrates. Thus, the present disclosure provides methods for achieving high-quality, reduced recombination passivation on silicon surfaces while maintaining good optical properties (including negligible optical absorption) that are needed for high performance solar cells through low-temperature processes. The processes disclosed herein comprise appropriate surface preparation and cleaning, growth and/or deposition of bi-layer thin films, e.g. hydrogenated silicon nitride on chemical oxide or on amorphous silicon, and final post-annealing. The low-temperature processes disclosed achieve surface recombination velocities that are equivalent to or lower than the results obtained using known high temperature thermal oxidation processes.

The described embodiments provide good surface passivation along with good optical properties for crystalline silicon substrates at lower processing temperatures—preferably at or below 250° C. and as low as 100° C. deposition and post-deposition. Yet another advantage of the disclosed subject matter is to provide processes for highly efficient surface passivation of silicon substrate based solar cells that may be readily incorporated into and used by existing manufacturing processes as well as future technologies that may require use of low temperature processing for surface passivation.

The disclosed subject matter provides a method for obtaining ultra-low surface recombination velocities from highly efficient surface passivation in crystalline (monocrystralline or multicrystalline) thin (1 μm to 150 μm) silicon substrate-based solar cells by utilizing a dual layer passivation scheme which also works as an efficient ARC. The dual layer passivation consists of a first thin layer of wet chemical oxide (such as a SiO₂ layer 1-3 nm thick) or a thin hydrogenated (preferably controlled hydrogenation) amorphous silicon layer (such as a-Si layer 1-10 nm thick) followed by depositing an amorphous hydrogenated silicon nitride film (SiNx:H 10-1000 nm) on top of the wet chemical oxide or amorphous silicon film. This deposition is then followed by anneal in N₂+H₂ ambient (forming gas anneal, FGA) or N₂ ambient at temperatures equal to or greater than the deposition temperature to further enhance the surface passivation.

Importantly, the hydrogenated amorphous silicon nitride thin film itself may be a bi-layer or multi-layer. In one embodiment, the hydrogenated amorphous silicon nitride thin film bi-layer may comprise a first layer with a higher index of refraction and higher relative silicon-to-nitrogen ratio and a second layer with a lower index of refraction and a lower silicon-to-nitrogen ratio. Thus the layer with the higher refractive index is positioned closer to the silicon substrate and the layer with the lower refractive index is positioned closer to the silicon substrate.

The two layers described above may be deposited in a single processing step or in sequential processing steps, within the same chamber, or with or without air exposure or a vacuum break. The silicon nitride and amorphous silicon films may be deposited using plasma enhanced chemical vapor deposition (PECVD) with direct or remote plasma of low frequency or high frequency, and using an in-line or batch/cluster tool. Other methods of deposition include low pressure chemical vapor deposition (LPCVD), physical vapor deposition (PVD), atmospheric chemical-vapor deposition (APCVD), plasma sputtering, or ion-beam deposition (IBD).

Surface pre-treatment plays a critical role prior to deposition of the passivation films. In the case of formation of dual layer passivation involving wet chemical oxide, the textured or flat silicon surface needs to be cleaned with solutions involving, but not limited to HF and HCl. Solutions with NH₄OH:H₂O₂ or HCl:H₂O₂ may also be used. The surface clean thus forms a clean hydrophobic hydrogen-passivated silicon surface. The surface clean step is then followed by an aqueous HNO₃ (10-50% dilution) dip at temperatures in the range of 20-80° C. or a DI water with ozone (DIO₃) dip or an ozonated DI water+dilute HF mixture dip (thereby hydrogen passivating the surface), which forms a wet chemical oxide layer in the range of 0.3-5 nm thick properly without any contaminants that may degrade the surface quality and hence surface passivation. The thickness of the oxide layer may be adjusted depending on desired properties, thus the disclosed subject matter includes all thicknesses in the disclosed range (such as 0.5-5 nm).

In the case of dual layer passivation involving amorphous silicon thin films, all of the native silicon oxides need to be removed from the surface. Other metallic and organic surface contaminants should also be removed. Thus the substrate is cleaned in dilute HF prior to deposition. The HF clean may be preceded by the surface clean involving solutions HF, HCl and/or NH₄OH:H₂O₂, HCl:H₂O₂ solutions. After proper surface treatment and cleaning, the deposition of chemical oxide or amorphous silicon and then the silicon nitride is carried out—thereby forming the dual stack bi-layer.

In the case of passivation involving wet chemical oxide and silicon nitride, the cleaned substrate with chemical oxide is introduced into the deposition chamber where silicon nitride 10-200 nm (or as thin as 10-100 nm) thick with refractive index between 1.85-2.3 (or 1.85-2.2 dependent on desired properties) is deposited using plasma enhanced chemical vapor deposition using SiH₄ and NH₃ at temperatures in the range of 100-500° C., or more particularly in the range of 100-450° C. Other process embodiments may utilize a silicon containing gas such as disilane (Si₂H₆) or a metal-organic silicon source as an ambient and a nitrogen and hydrogen containing gas such as, NH₃, H₂, and N₂ gas precursors. The thickness of the silicon nitride layer may be adjusted depending on desired properties, thus the disclosed subject matter includes all thicknesses in the disclosed range.

In the case of passivation involving hydrogenated amorphous silicon thin film (for example amorphous silicon a-Si, amorphous silicon containing oxygen and/or carbon a-SiOC, or amorphous silicon containing oxygen and/nitrogen a-SiON), the cleaned substrate having an oxide free surface (prepared by a dilute HF dip, for example) is introduced into the deposition chamber where a thin layer in the range of 1-10 nm thick of amorphous silicon is deposited using plasma enhanced deposition using SiH₄, with or without H₂ as a precursor, at temperatures in the range of 100-500° C., or more particularly 100-400° C. Other process embodiments may utilize silicon containing gas such as disilane (Si₂H₆) or an organo-silicon source, and an additional gas such as H₂ and N₂ gas precursors. The thickness of the silicon thin film may be adjusted depending on desired properties, thus the disclosed subject matter includes all thicknesses in the disclosed range. Further, embodiments of the hydrogenated amorphous silicon thin film include hydrogenated amorphous sub-stoichiometric silicon oxide, hydrogenated amorphous sub-stoichiometric silicon nitride, hydrogenated amorphous sub-stoichiometric silicon oxynitride, and hydrogenated amorphous sub-stoichiometric silicon carbide.

Following the amorphous silicon deposition a plasma enhanced chemical vapor deposition of a silicon nitride film with a thickness in the range of 10-200 nm (or as thin as 10-100 nm) and a refractive index between 1.85-2.3 (or 1.85-2.2 dependent on desired properties) is performed at temperatures in the range of 100-500° C., or more particularly 100-400° C. Process embodiments may utilize a silicon containing gas such as SiH₄, disilane (Si₂H₆), or a metal-organic silicon source as an ambient and a nitrogen and hydrogen containing gas such as, NH₃, H₂, and N₂ gas precursors. The thickness of the silicon nitride layer may be adjusted depending on desired properties, thus the disclosed subject matter includes all thicknesses in the disclosed range.

After deposition of the passivation stack, the substrate is annealed at preferably the same temperature as the temperature of deposition, although the annealing temperature may be higher (for example between 100-500° C., or more particularly 100-450° C.). Further, performing post anneal in a vacuum, in nitrogen or forming gas (N₂, H₂, NH₃, or forming gas ambient such as N₂+H₂) may improve the passivation. For example, maintaining the anneal temperature between 100-450° C. for about 1-120 minutes helps preserve the optical properties of the passivation layer for its conducive use as an anti-reflective coating (ARC) and improves the surface passivation. However, importantly the process embodiments of the disclosed subject matter may or may not utilize post-deposition annealing in forming gas or nitrogen.

An important aspect of the disclosed subject matter concerns finding the correct process-property relationship for the method of passivation where the key component of passivation, i.e. silicon nitride, has to be optimized for its dual role as passivation dielectric and efficient anti-reflective coating (ARC) providing efficient light trapping (such as by minimizing optical reflection losses). Deposition parameters for the hydrogenated amorphous silicon thin film and the hydrogenated amorphous silicon nitride thin film—such as temperature, gas flows of SiH₄, Si₂H₆, NH₃, H₂ and N₂, N₂O, CO₂, chamber pressure, and plasma power—may be optimized to provide for a relatively high Si—H bond density with minimal light absorption at all wavelengths 300-1600 cm-1.

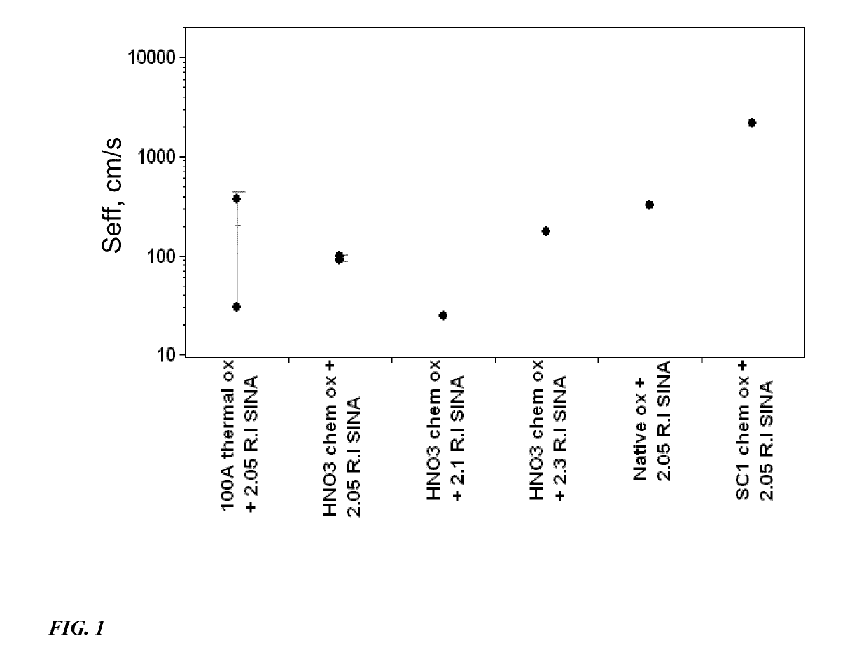

FIG. 1 is a graph presenting actual measured results as a comparison of surface passivation quality (Seff) with PECVD SiNx film refractive index (RI) on a dual layer stack with wet chemical oxide showing tuning deposition parameters of SiN at 400° C. Historically front (light receiving) side passivation is known to be improved with thermal oxide—which provides relatively low surface recombination velocities. Additionally, there have been extensive studies on the impact of silicon nitride deposition conditions and their impact on passivation. However, by utilizing the disclosed methods of dual layer passivation with anneal, the surface passivation improves quality dramatically—as shown by the measured results depicted in FIG. 1—and performs better than or equal to the performance of a dual layer stack of thermal (higher temperature) oxide and silicon nitride passivated surface at 400° C. A significant advantage of the disclosed processes is that the higher temperatures required for thermal oxide processing are not required in the disclosed bi-layer methods—thus reducing and avoiding the disadvantages associated with performing high temperature processes on thin film substrates.

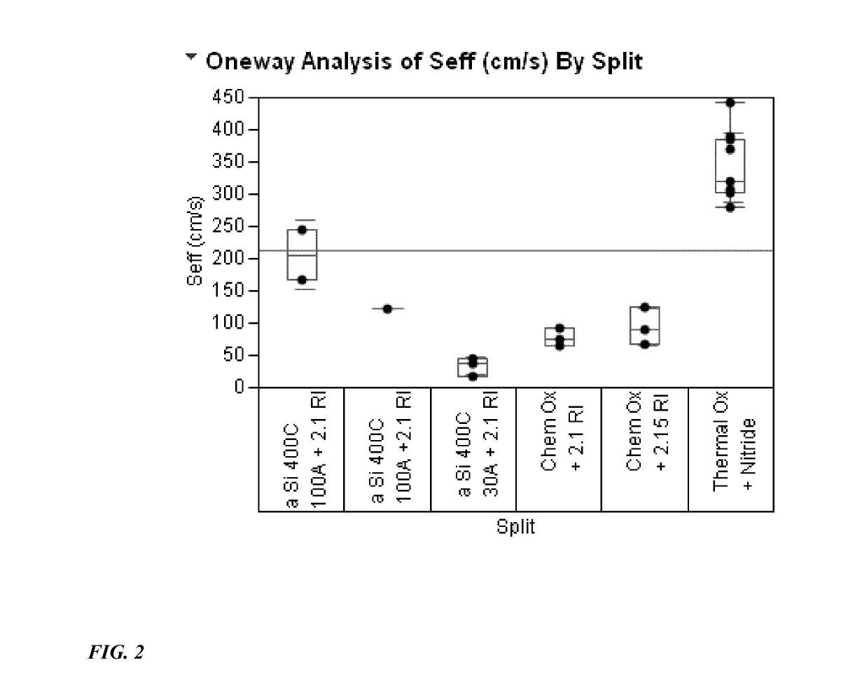

The disclosed subject matter comprises tuning the properties of deposited amorphous silicon and silicon nitride film to obtain optimal passivation. FIG. 2 is a graph presenting actual measured results showing a passivation quality comparison of 400° C. amorphous Si/SiN and chemical-oxide/400° C. SiN dual layer stack (bi-layer) with thermal (high-temp) oxide/SiN stack. Notice the equivalent or better performance of the amorphous-Si/SiN and chem-ox/SiN stack as a passivation layer as compared to the thermal (high-temp) oxide/SiN stack. The results depicted in the graph of FIG. 2—the measured interaction of deposition parameters and the impact of silicon nitride refractive index (RI) on passivation quality as measured by photo conductance decay—show that the RI between 2.0-2.3 works the best for passivation in dual layer passivation at a temperature of 400° C. when wet chemical oxide is used as one of the passivation layers.

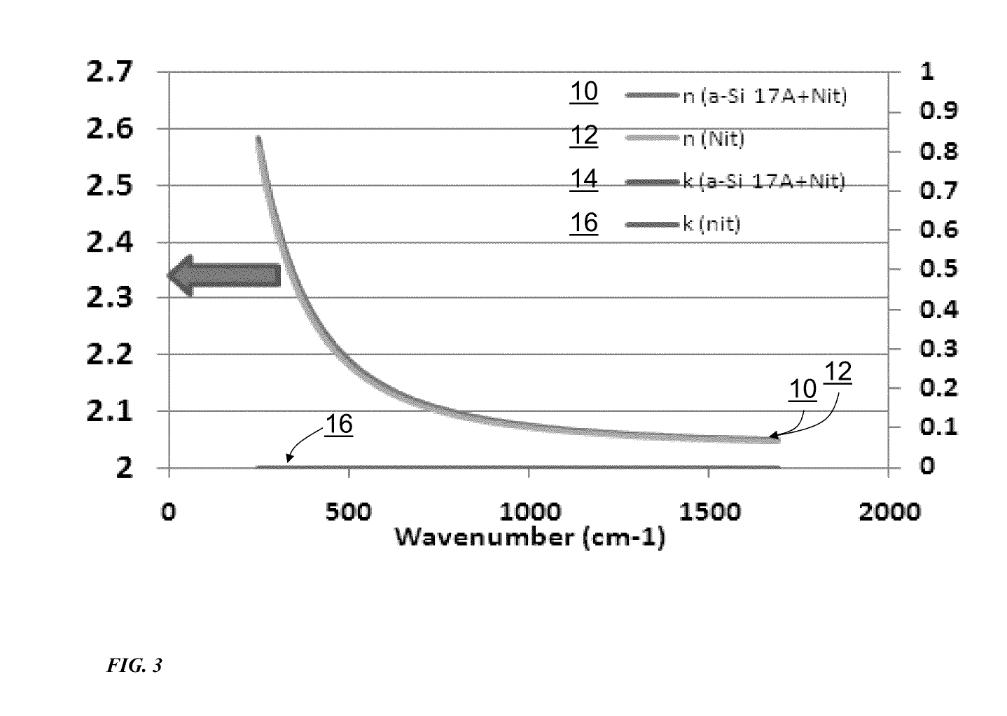

In the case of passivation bi-layer utilizing amorphous silicon as the first layer, deposition conditions and film thickness also impact passivation quality. FIG. 3 is a graph presenting actual measured results showing optical parameters i.e. refractive index(n) and extinction coefficient (k) vs wavelength for dual layer stack vs single layer SiN showing matched parameters with thin amorphous Si layer. As shown by the graph in FIG. 3, a thickness between 1-10 nm provides the best passivation without degradation in light absorption due to the presence of amorphous silicon layer. FIG. 3 also shows no change in extinction coefficient of the dual layer passivation stack with the presence of the thin amorphous silicon layer.

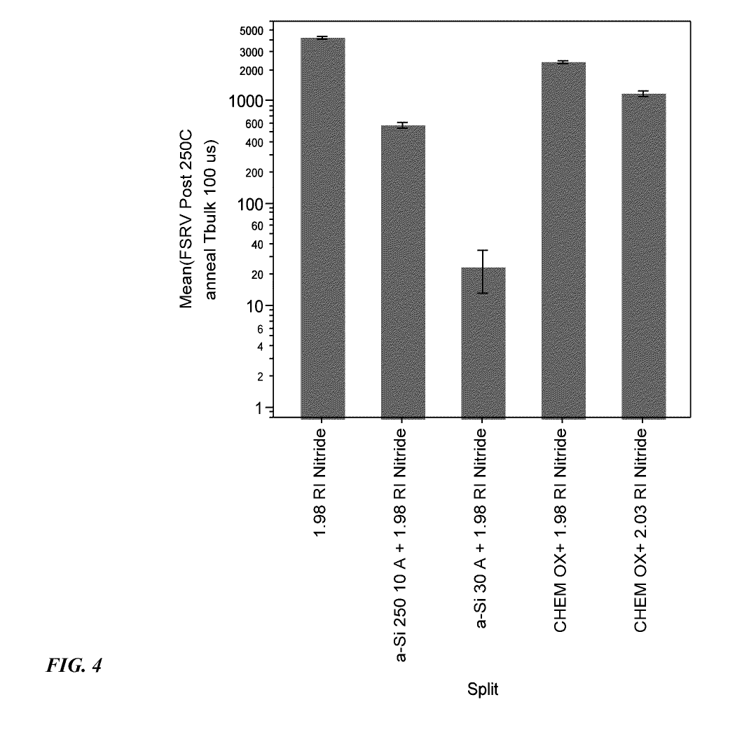

FIG. 4 is a graph presenting actual measured results showing passivation performance at 250° C. of dual layer stack (a-Si 10A and 30A/SiN and chem-ox/SiN)—note the 30A a-Si/SiN stack achieves better performance. In yet another embodiment, superior surface passivation is achieved at very low deposition temperatures ≦150° C. using hydrogenated amorphous silicon thin film (such as a-Si, a-SiOC or a-SiON) and silicon nitride dual layer passivation with post deposition anneal at temperatures that are the same as deposition temperature. Using this low temperature passivation scheme, the thin amorphous silicon layer (1-10 nm) is deposited on the cleaned silicon substrate at a temperature ≦150° C., as described previously, using SiH₄ with or without H₂ followed by silicon nitride deposition at ≦150° C. followed by anneal at the same temperature of deposition for 1-120 minutes in N₂ or FGA. As shown by the graph in FIG. 4, this method provides the same level of passivation as that of films deposited and annealed at temperatures 250° C. For lower temperature passivation the silicon nitride deposition parameters should be tuned to get an RI between 1.85-2.2.

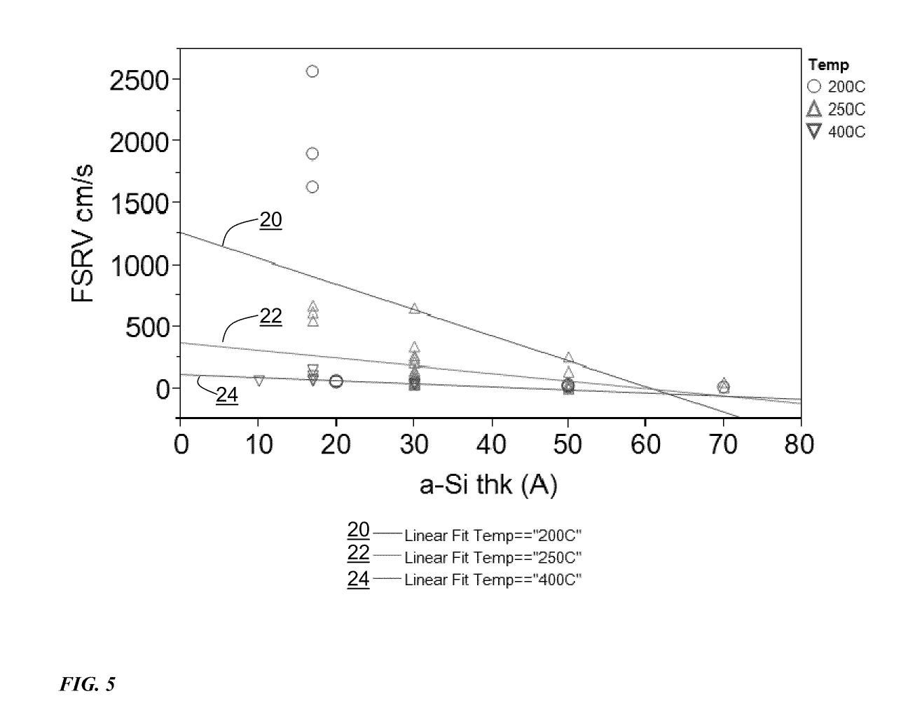

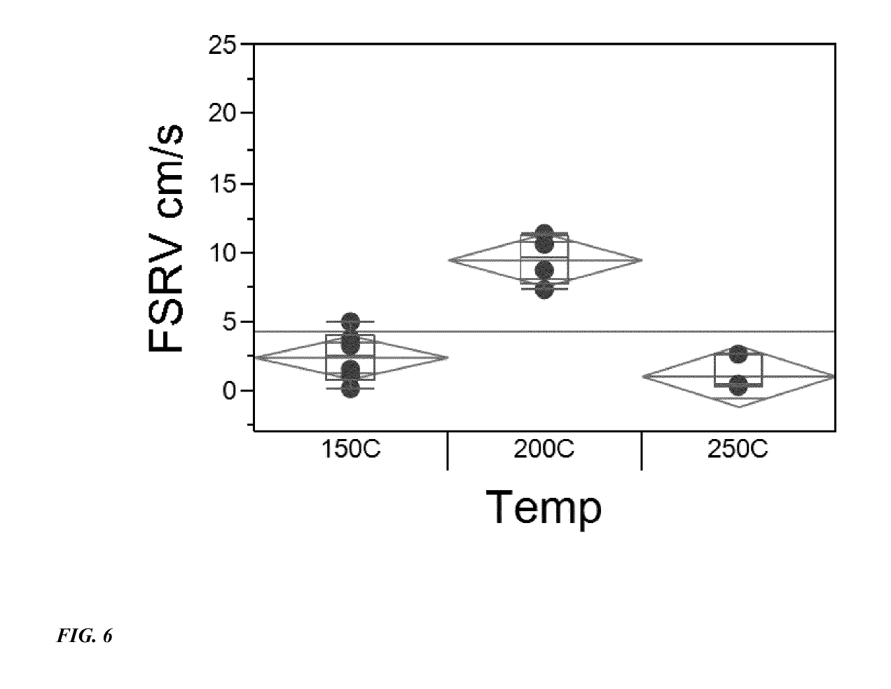

The disclosed methods further comprise tuning and adjusting the properties of deposited amorphous silicon and silicon nitride film to obtain optimal passivation at lower temperatures. FIG. 5 is a graph presenting actual measured results showing passivation (seff) vs amorphous Si layer thickness in an a-Si/SiN stack with varying processing temperatures showing equivalent performance at lower processing temperatures (such as 200° C.). As shown by the graph in FIG. 5, the measured impact of deposition parameters and the impact of amorphous silicon layer thickness shows that a thickness below 10 nm, and preferably between 3-10 nm, works best for passivation in dual layer passivation below 250° C. when amorphous silicon is used as one of the passivation layers. As shown by the graph in FIG. 6, understanding this relationship helped in reducing processing temperature further down to 150° C. FIG. 6 is a graph presenting actual measured results showing passivation (seff) vs temperature in a-Si/SiN stack with varying processing temperatures and showing equivalent performance at lower processing temperature at 150° C.

The methods provided give flexibility for silicon based device manufacturing as the passivation may be carried out in two steps or multiple steps if needed. For example, the formation of wet chemical oxide may be part of regular surface cleaning prior to deposition. Also, amorphous silicon deposition may be carried out in the same process step as that of silicon nitride or in the same chamber, adjacent chamber and with or without vacuum break.

While this disclosure describes reduced temperature surface passivation using dual-layer amorphous silicon and silicon nitride structures, additional embodiments also include structures which have bilayer or multilayer structures of amorphous silicon and/or bilayers or multilayer structures of silicon nitride (for example structures with different Si:N:H ratios in each layer). Moreover, for passivation layers which also serve as broadband Anti-Reflection Coating (ARC) layers in solar cells, the methods disclosed may also include additional materials deposited or formed on top of the passivation/ARC structures described.

In operation, the passivation methods described above are useful when the manufacturing methods require very low temperatures, for example <250° C., for passivation of the front/top (light receiving) side of the silicon substrate. The bi-layer methods disclosed provide good quality surface passivation with low surface recombination of minority carriers obtained at low temperatures of deposition followed by low temperature anneal. Further, the bi-layer passivation methods disclosed are particularly applicable for passivation of the front/top (light receiving) side of a thin film back contact back junction silicon solar cell because the low temperature processing is preferable for thin film substrates while maintaining the superior optical properties required for the light receiving surface of a back contact back junction solar cell. Additionally, the bi-passivation methods disclosed may include a thin, less than 80 microns, silicon (monocrystalline or multicrystalline) absorber layer.

The foregoing description of the preferred embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

What is claimed is:

1. A method for bi-layer passivation on a surface of a silicon substrate, comprising:
forming a thin chemical oxide layer on said surface;
depositing a hydrogenated amorphous silicon nitride thin film at a temperature substantially in the range of 100-500° C. on said chemical oxide thin film; and
subsequently annealing said silicon substrate at a temperature substantially in the range of 100-500° C.

2. The method of claim 1 wherein said bi-layer passivation is applied to the light receiving side of a high-efficiency back-contact/back-junction crystalline silicon solar cell.

3. The bi-layer passivation method of claim 1, further comprising the step of cleaning said silicon surface before the formation of said chemical oxide thin film in order to form a clean hydrophobic hydrogen-passivated silicon surface.

4. The bi-layer passivation method of claim 3, wherein said cleaning of said silicon surface utilizes a cleaning solution selected from the group consisting of NH4OH, H2O2, HCl followed by removal of the native oxide and hydrogen passivating the surface by a diluted HF solution.

5. The method of claim 1, wherein said thin chemical oxide layer has a thickness in the range of 0.3 to 5 nm and is formed in a HNO3 aqueous solution at a temperature in the range of 20-80° C.

6. The method of claim 1, wherein said deposition of said hydrogenated amorphous silicon nitride thin film is performed in an in-line or batch/cluster tool utilizing one of the following processes: plasma enhanced chemical vapor deposition (PECVD), low pressure chemical vapor deposition (LPCVD), atmospheric chemical-vapor deposition (APCVD), or physical vapor deposition (PVD).

7. The method of claim 1, wherein said deposition of said hydrogenated amorphous silicon nitride thin film comprises a first layer with a higher index of refraction and higher relative silicon-to-nitrogen ratio and a second layer with a lower index of refraction and lower silicon-to-nitrogen ratio.

8. The method of claim 1, wherein said deposition of said hydrogenated amorphous silicon nitride thin film further comprises positioning said silicon substrate into a plasma enhanced chemical vapor deposition (PECVD) chamber and depositing an amorphous silicon nitride film having a thickness in the range of 10-200 nm at temperatures in the range of 100 C-500° C. utilizing at least one silicon-containing gas selected from the group of SiH4, Si2H6, or metal-organic silicon sources, and at least one nitrogen and hydrogen containing gas selected from the group of NH3, H2, and N2 gas precursors, and the silicon nitride deposition conditions are tuned to obtain a refractive index between 1.85 and 2.3.

9. The method of claim 8, wherein said silicon nitride thin film comprises a stack of at least two silicon nitride films with two different refractive indices, the layer with the higher refractive index positioned closer to said silicon substrate and the layer with the lower refractive index positioned farther from said silicon substrate.

10. The method of claim 1, wherein said hydrogenated amorphous silicon nitride film has a thickness in the range of 10-200 nm, the deposition parameters such as temperature, gas flows of SiH4, Si2H6, NH3, H2, and N2, chamber pressure, and plasma power are optimized to provide for a relatively high Si—H bond density for improved surface passivation, and the refractive index is maintained between 1.85-2.2 for an antireflection coating with minimal light absorption at all wavelengths 300-1600 cm-1.

11. The method of claim 1, wherein said step of annealing said silicon substrate further comprises annealing said silicon substrate in a vacuum, or N2, H2, NH3, or forming gas (N2+H2) ambient for 1-120 minutes at or above the temperature of deposition of amorphous silicon nitride thin film.

12. A method for bi-layer passivation on a surface of a silicon substrate, comprising:
cleaning said surface of said silicon substrate to remove native oxides and other metallic and organic surface contaminants;
depositing a hydrogenated amorphous silicon thin film at a temperature substantially in the range of 100-500° C. on said surface of said silicon substrate;
depositing a hydrogenated amorphous silicon nitride thin film at a temperature substantially in the range of 100-500° C. on said hydrogenated amorphous silicon thin film; and
annealing said silicon substrate at a temperature substantially in the range of 100 C-500° C.

13. The method of claim 12, wherein hydrogenated amorphous silicon thin film is selected from the group consisting of amorphous silicon (a-Si), amorphous silicon containing oxygen and/or carbon (a-SiOC) or amorphous silicon containing oxygen and/or nitrogen (a-SiON).

14. The method of claim 12 wherein said bi-layer passivation is applied to the frontside light receiving side of a high-efficiency back-contact/back-junction crystalline silicon solar cell.

15. The method of claim 12, wherein said cleaning of said surface of said silicon substrate utilizes a cleaning solution selected from the group consisting of NH4OH, H2O2, HCl followed by removing the native oxide by a diluted HF solution.

16. The method of claim 12, wherein said deposition of said hydrogenated amorphous silicon thin film and said hydrogenated amorphous silicon nitride thin film is performed in an in-line or batch/cluster tool utilizing one of the following processes: plasma enhanced chemical vapor deposition (PECVD), low pressure chemical vapor deposition (LPCVD), atmospheric chemical-vapor deposition (APCVD), or physical vapor deposition (PVD).

17. The method of claim 16, wherein said deposition of said hydrogenated amorphous silicon nitride thin film comprises a first layer with a higher index of refraction and higher relative silicon-to-nitrogen ratio and a second layer with a lower index of refraction and lower silicon-to-nitrogen ratio.

18. The method of claim 12, wherein said steps of depositing a hydrogenated amorphous silicon thin film and depositing a hydrogenated amorphous silicon nitride thin film further comprise the steps of:
positioning said cleaned silicon substrate in a plasma enhanced chemical vapor deposition chamber and depositing a hydrogenated amorphous silicon thin film having a thickness in the range of 1-10 nm at temperatures in the range of 100 C-500° C. utilizing a silicon-containing gas from the group of SiH4, Si2H6, or an organo-silicon source, and at least one additional gas from the group of H2, N2 gas precursors; and
depositing a hydrogenated amorphous silicon nitride thin film having a thickness in the range of 10-200 nm at temperatures in the range of 100 C-500° C. using a silicon-containing gas from the group of SiH4, Si2H6, or an organo-silicon precursor, as well as at least one nitrogen and hydrogen containing gas from the group of NH3, H2, and N2 gas precursors, and the silicon nitride deposition conditions are tuned to obtain a refractive index between 1.85-2.3.

19. The method of claim 18, wherein said silicon nitride thin film comprises a stack of at least two silicon nitride films with two different refractive indices, the layer with the higher refractive index positioned closer to said silicon substrate and the layer with the lower refractive index positioned farther from said silicon substrate.

20. The method of claim 12, wherein said hydrogenated amorphous silicon thin film has a thickness in the range of 1-10 nm and the deposition parameters such as temperature, gas flows of SiH4, Si2H6, NH3, H2, and N2, N2O, CO2, chamber pressure, and plasma power are optimized to provide for a relatively high Si—H bond density with minimal light absorption at all wavelengths 300-1600 cm-1.

21. The method of claim 12, wherein said hydrogenated amorphous silicon nitride thin film has a thickness in the range of 10-200 nm and the deposition parameters such as temperature, gas flows of SiH4, Si2H6, NH3, H2, and N2, chamber pressure, and plasma power are optimized provide for a relatively high Si—H bond density, and refractive index is maintained between 1.85-2.2 for an antireflection coating with minimal light absorption at all wavelengths 300-1600 cm-1.

22. The method of claim 12, wherein the deposition of amorphous silicon nitride and amorphous silicon thin films may be deposited at the same deposition temperature and in the same chamber or tool to eliminate vacuum break and ambient air exposure between depositions of amorphous silicon nitride and amorphous silicon.

23. The method of claim 12, wherein said step of annealing said silicon substrate further comprises annealing said substrate in a vacuum, or N2, H2, NH3, or forming gas (N2+H2) ambient for 1-120 minutes at or above the temperature of deposition of said amorphous silicon and amorphous silicon nitride thin films.

24. A surface-passivated crystalline silicon solar cell substrate comprising:
a doped substrate bulk layer;
a diffused sub-surface layer positioned on said substrate bulk layer and doped with a dopant having a polarity opposite said doped substrate bulk layer; and
a passivated surface bi-layer thin film annealed at temperatures in the range of 100-500° C. and positioned on said sub-surface layer and forming the light receiving side of said silicon solar cell.

25. The surface-passivated crystalline silicon solar cell substrate of claim 24, wherein said passivated bi-layer thin film comprises a first layer of chemical oxide having a thickness in the range of 0.5-5 nm and a second layer of silicon nitride positioned on said first layer and having a thickness in the range of 10-200 nm.

26. The passivated silicon solar cell substrate of claim 24, wherein said passivated bi-layer thin film comprises a first layer of amorphous silicon having a thickness in the range of 1-10 nm and a second layer of silicon nitride positioned on said first layer and having a thickness in the range of 10-200 nm.

27. A high-efficiency back-contact, back-junction thin monocrystalline silicon solar cell comprising a thin monocrystalline silicon absorber with a thickness of less than 80 microns and a light-receiving surface passivated with a bi-layer structure comprising a thicker top layer of hydrogenated silicon nitride with a thickness in the range of 10 to 200 nm and a thinner bottom layer of hydrogenated amorphous silicon with a thickness in the range of 1 to 10 nm.

28. The high-efficiency back-contact, back-junction thin monocrystalline silicon solar cell of claim 27, wherein said thinner bottom layer is hydrogenated amorphous sub-stoichiometric silicon oxide with a thickness range in the range of 1 to 10 nm.

29. The high-efficiency back-contact, back-junction thin monocrystalline silicon solar cell of claim 27, wherein said thinner bottom layer is hydrogenated amorphous sub-stoichiometric silicon nitride with a thickness in the range of 1 to 10 nm.

30. The high-efficiency back-contact, back-junction thin monocrystalline silicon solar cell of claim 27, wherein said thinner bottom layer is hydrogenated amorphous sub-stoichiometric silicon oxynitride with a thickness in the range of 1 to 10 nm.

31. The high-efficiency back-contact, back-junction thin monocrystalline silicon solar cell of claim 27, wherein said thinner bottom layer is hydrogenated amorphous sub-stoichiometric silicon carbide with a thickness in the range of 1 to 10 nm.
